(19) United States
(12) Patent Application Publication
(10) Pub. No.: US 2025/0212523 A1
(43) Pub. Date: Jun. 26, 2025

(54) SIGNAL ROUTING PATH USING FREE BACKSIDE WIRES

(71) Applicant: INTERNATIONAL BUSINESS MACHINES CORPORATION, Armonk, NY (US)

(72) Inventors: James P Mazza, Saratoga Springs, NY (US); Ruilong Xie, Niskayuna, NY (US); Nicholas Anthony Lanzillo, Wynantskill, NY (US); Koichi Motoyama, Clifton Park, NY (US)

(21) Appl. No.: 18/390,420

(22) Filed: Dec. 20, 2023

(51) Int. Cl. H01L 27/02; H01L 27/092; H01L 29/06; H01L 29/417; H01L 29/78

(52) U.S. Cl. CPC H10D 89/10; H10D 30/668; H10D 62/119; H10D 64/252; H10D 84/853

(57) ABSTRACT

A semiconductor device includes an electrical pathway connecting a frontside of the semiconductor device to a backside of the semiconductor device. The electrical pathway includes a backside wire disposed within a backside interconnect layer. A first deep via connects to the backside wire, the first deep via extending through a front end of line (FEOL) region. A local interconnect connects to and extends transversely to the first deep via to connect the backside wire to a frontside component.

### BACKGROUND

The present invention generally relates to semiconductor devices and processing methods, and more particularly to employing free wires on a backside of a semiconductor device to route signal lines for the semiconductor device.

Semiconductor devices include multiple levels of metal lines. These crisscrossing lines along with contacts and vias make up a large portion of signal routing circuits. With advances in semiconductor technology and decreasing node sizes, signal line routing resources have been pushed to their limits. Stacked field effect transistor (SFET) devices may be used to increase areal density of devices on a chip. Positioning transistors in close proximity places spatial and electrical constraints that can make it challenging to provide required performance.

An additional challenge arises in providing electrical connections to these transistors. Contact and wire routing have increasingly less space and therefore fewer options. To increase routability of wires, all available space needs to be considered.

Therefore, a need exists for new wiring structures that permit circuit routing without displacing earlier formed wiring components, e.g., contacts, metal lines, etc. A further need exists for new wiring structures that provide additional wiring options for increasingly dense metal structures on semiconductor devices. Such options are particularly useful if there is no associated area penalty when implementing these options.

### SUMMARY

In accordance with an embodiment of the present invention, a semiconductor device includes an electrical pathway connecting a frontside of the semiconductor device to a backside of the semiconductor device. The electrical pathway includes a backside wire disposed within a backside interconnect layer and a first deep via connecting to the backside wire. The first deep via extends through front end of the line (FEOL) structures to connect the backside wire to a frontside component, wherein the first deep via connects to the frontside component by a local interconnect that extends transversely to the first deep via.

In accordance with an embodiment of the present invention, a semiconductor device includes an electrical pathway connecting a frontside of the semiconductor device to a backside of the semiconductor device. The electrical pathway includes a backside wire disposed within a backside interconnect layer. A first deep via connects to the backside wire, the first deep via extending through a front end of line (FEOL) region. A local interconnect connects to and extends transversely to the first deep via to connect the backside wire to a frontside component.

In other embodiments, the first deep via can connect to the frontside component by a local interconnect that extends transversely to the first deep via. The local interconnect can extend over a FEOL structure in the FEOL region. The local interconnect can connect to the FEOL structure or the local interconnect can be electrically isolated from the FEOL structure that it extends over. A second deep via can connect the backside wire to a FEOL structure. The second deep via can be disposed between gate structures of FEOL structures. The first deep via can be disposed between gate structures of FEOL structures. The backside wire can be disposed transverse to the gate structures. The backside wire can be disposed between power nets within the backside interconnect layer. The frontside component can include an M1 metal line.

In accordance with another embodiment of the present invention, a semiconductor device includes FEOL structures disposed between a frontside and a backside of the semiconductor device and an electrical pathway connecting the frontside to the backside. The electrical pathway includes a backside wire disposed within a backside interconnect layer, a first deep via connecting to a first end portion of the backside wire and a second deep via connecting to a second end portion the backside wire opposite the first end portion. The first deep via and the second deep extend through the FEOL structures to connect the backside wire to the frontside of the semiconductor device.

In other embodiments, the first deep via can connect to the frontside by a local interconnect that extends transversely to the first deep via. The local interconnect can extend over a source/drain region of one of the FEOL structures. The local interconnect can connect to the FEOL structure or the local interconnect can be electrically isolated from the FEOL structure that it extends over. The first and second deep vias can be disposed between gate structures of the FEOL structures. The backside wire can be disposed transversely to the gate structures. The backside wire can be disposed between power nets within the backside interconnect layer. The backside wire can connect to an M1 metal line on the frontside.

In accordance with another embodiment of the present invention, a semiconductor device, includes FEOL structures disposed between a frontside and a backside of the semiconductor device. A frontside contact layer includes frontside contacts to connect to the FEOL structures from a frontside, and a backside contact layer includes backside contacts to connect to the FEOL structures from a backside. A backside wire is disposed within a backside interconnect layer. A first deep via extends through the FEOL structures and connects to the backside wire using with the backside contacts. A second deep via extends through the FEOL structures and connects to the backside wire using with the backside contacts. The first deep via and the second deep connect the backside wire to the frontside of the semiconductor device.

In some embodiments, the first deep via can connect to the frontside by a local interconnect that extends transversely to the first deep via over a source/drain region of one of the FEOL structures. The first and second deep vias can be disposed between gate structures of the FEOL structures, and the backside free wire can be disposed transversely to the gate structures. The backside wire can be disposed between power nets within the backside interconnect layer.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 shows cross-sectional views X1, X2 and Y1 taken at section lines X1, X2 and Y1 in a layout view showing a semiconductor device having a row of source/drain regions, with associated placeholders, and gate structures, in accordance with an embodiment of the present invention;

FIG. 2 shows cross-sectional views X1, X2 and Y1 taken at section lines X1, X2 and Y1 in the layout view showing the semiconductor device after dummy gate removal and replacement metal gate formation, the layout view also showing gate cut formation, in accordance with an embodiment of the present invention;

FIG. 3 shows cross-sectional views X1, X2 and Y1 taken at section lines X1, X2 and Y1 in the layout view showing the semiconductor device after frontside deep vias and contacts are formed, in accordance with an embodiment of the present invention;

FIG. 4 shows cross-sectional views X1, X2 and Y1 taken at section lines X1, X2 and Y1 in the layout view showing the semiconductor device after a local interconnect, metal lines and back end of the line structures are formed, in accordance with an embodiment of the present invention;

FIG. 5 shows cross-sectional views X1, X2, Y1 and Y2 taken at section lines X1, X2, Y1 and Y2 in the layout view showing the semiconductor device after a substrate portion is removed, in accordance with an embodiment of the present invention;

FIG. 6 shows cross-sectional views X1, X2, Y1 and Y2 taken at section lines X1, X2, Y1 and Y2 in the layout view showing the semiconductor device after removing the remainder of the substrate and forming a backside interlevel dielectric layer, in accordance with an embodiment of the present invention;

FIG. 7 shows cross-sectional views X1, X2, Y1 and Y2 taken at section lines X1, X2, Y1 and Y2 in the layout view showing the semiconductor device after backside contact patterning, in accordance with an embodiment of the present invention;

FIG. 8 shows cross-sectional views X1, X2, Y1 and Y2 taken at section lines X1, X2, Y1 and Y2 in the layout view showing the semiconductor device after select placeholders have been removed and backside contacts have been formed, in accordance with an embodiment of the present invention;

FIG. 9 shows cross-sectional views X1, X2, Y1 and Y2 taken at section lines X1, X2, Y1 and Y2 in the layout view showing the semiconductor device after a backside interconnect layer including a backside wire is formed, in accordance with an embodiment of the present invention;

FIG. 10 shows a layout view of a signal path that passes through a front end of the line (FEOL) region of the device to connect a frontside to a backside of the device, in accordance with an embodiment of the present invention; and

FIG. 11 shows a layout view of a signal path that utilizes filler cells to route a signal path, in accordance with an embodiment of the present invention.

### DETAILED DESCRIPTION

In accordance with embodiments of the present invention, devices and methods are described which include connections between components of a semiconductor device to enable additional wire routing possibilities. In one embodiment, unused backside routing resources are enabled to significantly reduce a number of frontside resources employed in a single net. Filler cells having contacts or via shapes can be used to connect metal lines with no area penalty. The components can connect without interfering with source/drain region contacts, gate contacts or other structures.

In an embodiment, a semiconductor device includes a backside contact under an active source/drain (S/D) region, which connects the S/D region to backside power. A first deep via contact wires a first S/D region under first metal tracks to a backside wire. A second deep via contact wires the backside wire to a frontside interconnect with second metal tracks through a local interconnect. The local interconnect can be formed over a S/D region with a backside contact. The local interconnect can connect to the S/D region, or the local interconnect can be electrically isolated from the S/D region that it extends over. The backside contact can be formed under the first and second deep vias. The first and second deep vias can be located in between gates over non-active regions. The first and second deep vias can traverse a row of S/D regions to provide a pathway between a backside and a frontside of the semiconductor device. In an embodiment, the backside power wires can be located under active regions while the backside wire can be located under non-active regions.

A new wiring structure is provided that permits circuit routing without displacing earlier formed wiring components, e.g., contacts, metal lines, etc. The present embodiments permit wiring access into an active area of the device through pathways that were not accessible in the past, e.g., between a frontside and a backside of the device. This provides flexibility and opens up additional wiring options for increasingly dense metal structures on semiconductor devices.

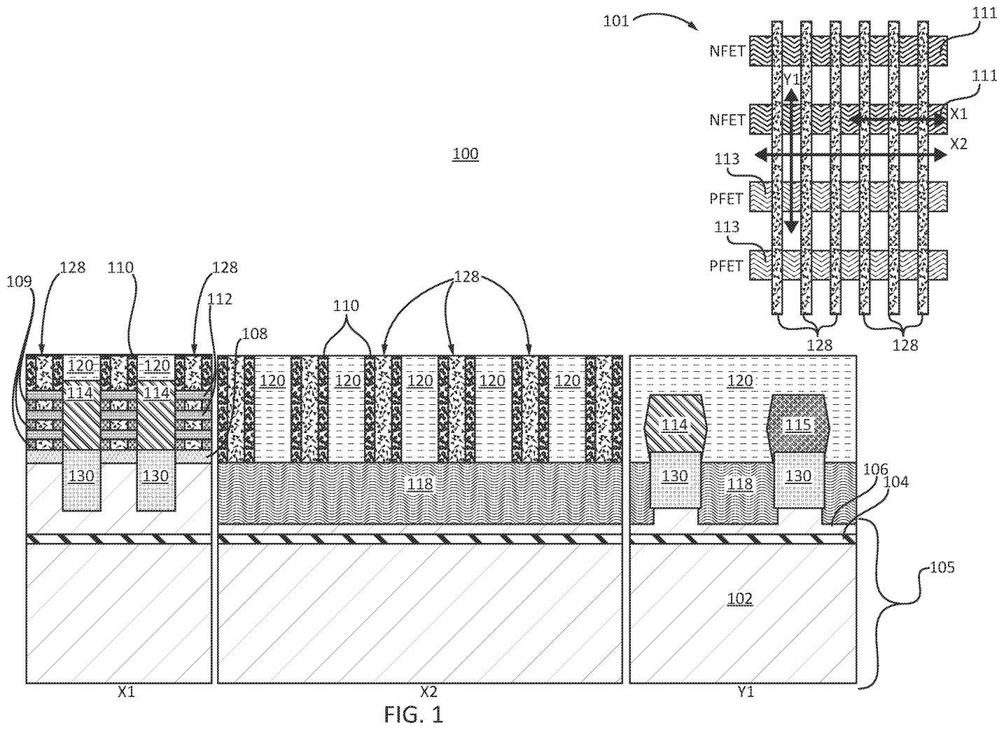

Referring now to the drawings in which like-numerals represent the same or similar elements and initially to FIG. 1, devices and methods for manufacturing a semiconductor device are shown in accordance with embodiments of the present invention. The semiconductor device can include a nanosheet channel field effect transistor (FET) device, where a frontside (or top) or region and a backside (or bottom) or region of the device are processed to include FETs; however, embodiments of the present invention can be employed in or any other semiconductor device where efficient wire routing is needed or useful.

A layout view 101 shows a wafer 100 having active regions 111 and 113 and gate structures 128. The layout view shows section lines X1, X2, and Y1 where correspondingly indicated cross-sections are taken. In one embodiment, active regions 111 include diffusion regions for N-type field effect transistors (NFETs), and active regions 113 includes diffusion regions for P-type field effect transistors (PFETs). Different combinations of NFETs and PFETs are also contemplated. The active regions 111, 113 include S/D regions 114, 115 separated by gate structures 128 and channels (located beneath gate structures 128) provided by semiconductor layers 112 (depicted in section X1). Gate structures 128 have a longitudinal axis that is transversely disposed to a longitudinal axis of the active regions 111, 113.

Wafer 100 includes a substrate 105 having multiple layers on which the semiconductor device will be fabricated. The substrate 105 can include any suitable substrate structure or material, e.g., a bulk semiconductor, a semiconductor-on-insulator (SOI) substrate, etc., and preferably includes a monocrystalline semiconductor. In one example, the substrate 105 can include a substrate portion 102, etch stop layer 104 and semiconductor portion 106. Substrate portion 102 and semiconductor portion 106 can include silicon-containing material. Illustrative examples of Si-containing materials suitable for the portions 102, 106 can include, but are not limited to, Si, SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc.

An etch stop layer 104 is formed on the substrate portion 102. The etch stop layer 104 can include an epitaxially grown crystal structure. The etch stop layer 104 includes a material that permits the selective etching and removal of the substrate portion 102 in later steps. In one embodiment, the etch stop layer 104 includes SiGe although depending on the material of the portions 102, 106, other materials can be selected, e.g., SiGeC, SiC, etc.

Semiconductor portion 106 is provided on the etch stop layer 104. The semiconductor portion 106 can include a same material as the substrate portion 102, although other semiconductor materials can be employed, e.g., SiGe, SiGeC, SiC, etc.

Shallow trench isolation 118 is formed in the substrate portion 106 by filling trenches formed therein with dielectric material, e.g., silicon oxide or the like.

A layer stack or stacks are applied to or formed on the semiconductor portion 106. In one embodiment, one or more nanosheets (NS) are applied to the semiconductor portion 106. In another embodiment, the layer stacks can be epitaxially grown using different chemistries to form layers having different properties. In an embodiment, a layer stack includes semiconductor layers 112, which function as channels between source/drain regions 114, 115. The S/D regions 114, 115 have associated placeholders 130 formed in trenches within the semiconductor portion 106. In one embodiment, the semiconductor portion 106 includes Si, and the placeholders 130 include SiGe, to provide selectable etching between the semiconductor portion 106 and the placeholders 130.

In some embodiments, active regions 111, 113 include S/D regions 114, 115 laterally disposed relative to one another in a row. In this illustrative embodiment, S/D regions 114 correspond with N-type doping and S/D regions 115 correspond with P-type doping. Regions between adjacent source/drain regions 114, 115 include the gate structures 128, which at this point in the fabrication process include a dummy of sacrificial material. The gate structures 128 can have device channels (semiconductor layers 112, e.g., from the nanosheets) passing therethrough. Other device architectures are also contemplated and the gate structures and the device channels can take other forms.

The gate structures 128 are formed between S/D regions 114, 115. The gate structures 128 can include high dielectric constant (high-K) gate dielectric (not shown) in contact with semiconductor layers 112 which form the device channels, in this illustrative example. A bottom dielectric interface (BDI) 108 and inner spacers 109 are formed for insulating a gate conductor to be formed in later steps when the dummy gate material is replaced with a gate metal which is also electrically isolated by dielectric sidewall spacers 110.

A dielectric layer 120, such as, e.g., an interlevel dielectric layer (ILD) is formed. The dielectric layer 120 can include any suitable material, e.g., selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). The dielectric layer 120 can be deposited using chemical vapor deposition (CVD), although other deposition methods can be employed. A planarization of a top free surface can be performed, e.g., using a chemical mechanical polish (CMP) process.

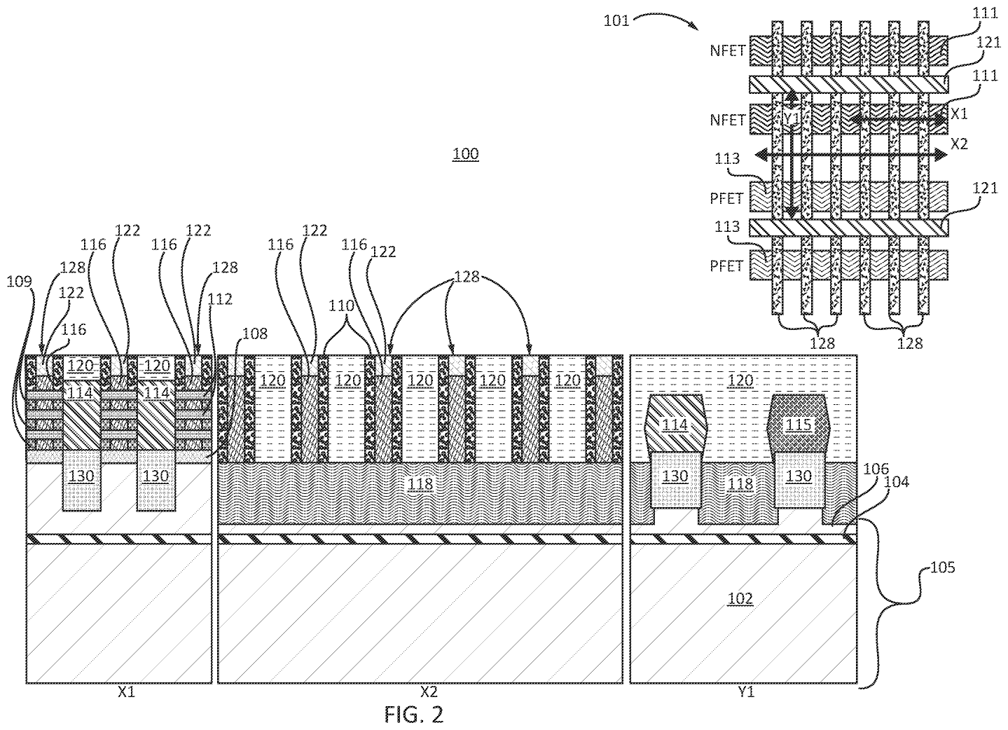

Referring to FIG. 2, dummy material is removed from the gate structures 128 and replaced with a gate metal 116 to form a gate electrode (replacement metal gate (RMG) over a gate dielectric. The gate structures 128 can include High-K Metal Gate (HKMG) structures, which selectively activate FETs that employ S/D regions 114, 115. The gate metal 116 is electrically isolated from semiconductor portion 106 by the bottom dielectric interface (BDI) 108. The gate metal 116 is also electrically isolated by dielectric sidewall spacers 110 and inner spacers 109.

The gate metal 116 is recessed and self-aligned contact caps 122 are formed in the recess at the tops of the gate structures 128. The gate structures 128 are transversely segmented by performing a gate cut process that etches trenches and fills the trenches with dielectric material to form gate cuts 121 shown in the layout view 101. The gate cuts 121 can include dielectric material such as a silicon oxide, although other dielectric materials can be employed.

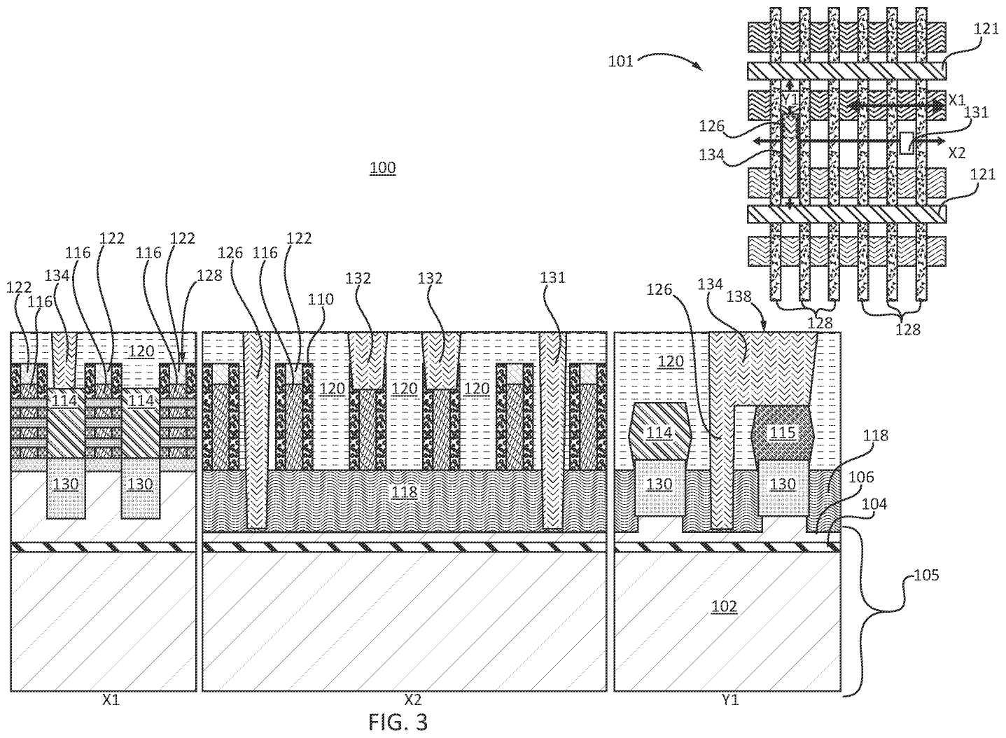

Referring to FIG. 3, middle of the line (MOL) contacts 132, 134 and deep vias 126, 131 are formed. The contacts 132, 134 form a frontside contact layer that includes frontside contacts to connect to, e.g., FEOL structures on a frontside of the semiconductor device under fabrication.

Contacts 132 are gate contacts that connect to gate metal 116 in gate structures 128. Contacts 134 make connections with the S/D regions 114, 115. Deep vias 126, 131 extend into the shallow trench isolation 118. A conductive structure 138 includes a contact 134 and a deep via 126. The conductive structure 138 is formed to provide local free wire access for a wire routing path to be completed in later steps.

In the layout view 101, deep vias 126 and 131 pass from a frontside to a backside of the semiconductor device under fabrication. Contacts 132 have been omitted in the layout view for viewing clarity. The contacts 132, 134 and deep vias 126, 131 can be patterned and etched in a same process or in separate processes. For contact 134, a silicide liner (not shown), such as Ti, Ni, NiPt can be deposited first since a connection is being made to S/D region 115. A diffusion barrier (not shown) can be formed in the trenches prior to a conductive fill for all contacts and vias, as needed. The diffusion barrier can include, e.g., TiN, TaN, or similar materials. The contacts 132, 134 and deep vias 126, 131 can include materials, such as, e.g., Cu, Ru, Mo, Rh, W, Ir, and alloys or combinations of these and other conductive materials. The conductive fill can include a chemical vapor deposition (CVD) or other deposition process. After the conductive fill a planarization process, such as a CMP can be performed.

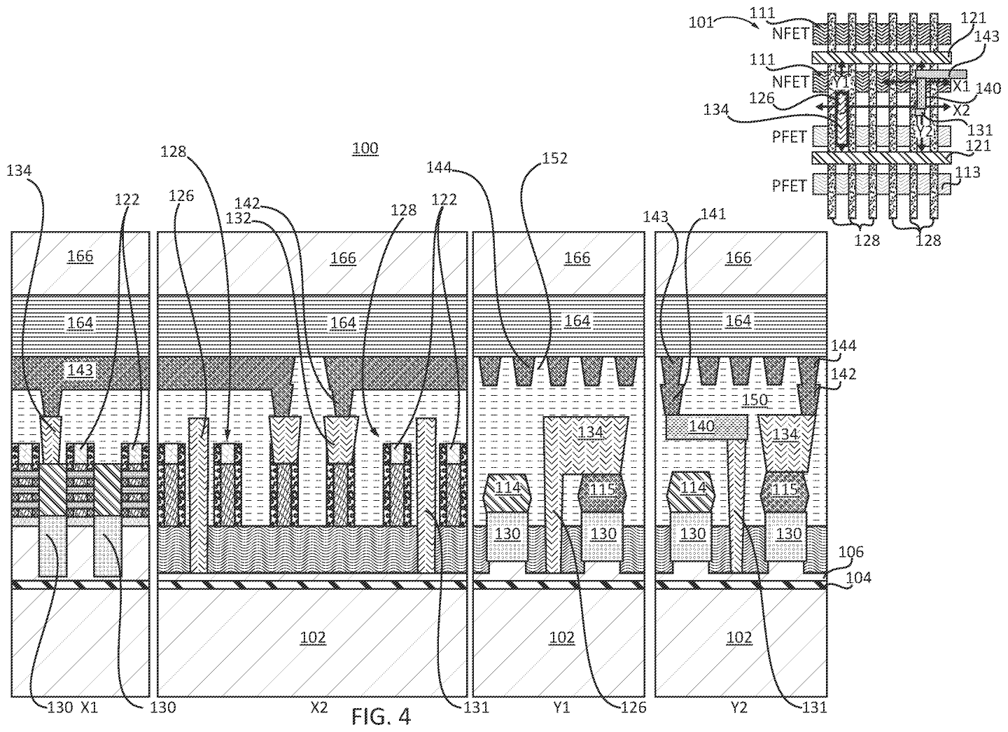

Referring to FIG. 4, an additional cross-sectional view, Y2, taken at section line Y2 in the layout view 101 is shown. A local interconnect 140 is formed to connect with deep via 131. The local interconnect 140 can be formed by patterning the dielectric layer 120 to expose the deep via 131 and then a conductive fill can be deposited and planarized similarly to the conductive fill described with reference to FIG. 3. Local interconnect 140 can be formed over an active S/D region 114. The S/D region 114 over which local interconnect 140 is formed does not include a S/D region contact. As such, the space is available to route a signal line or other wire.

A dielectric layer 150 is formed over the local interconnect 140 and patterned to form holes for vias 142, e.g., in a via layer V0. The dielectric layer 150 can include a same or different dielectric material as described for dielectric layer 120. Vias 142 are formed using a conductive fill process and can include any suitable conductive material. A via 141 makes a connection to the local interconnect 140 to connect the local interconnect 140 through the V0 layer (having via 141) to a metal 1 layer (M1) having metal lines 144.

Another dielectric layer 152 is formed over the via layer V0. The dielectric layer 152 can include a same or different dielectric material as described for dielectric layers, 150, 120. Metal lines 144 are formed by patterning the dielectric layer 152 and depositing a metal, e.g., Ru, although other conductive materials can be employed. The metal lines 144 can include the metal 1 (e.g., M1) layer although connection to higher metal layers are also contemplated. Metal line 143 connects to the via 141 and the local interconnect 140. The local interconnect 140 is connected to the deep via 131. The layout view 101 omits other contacts and connections for viewing clarity. The via 141 makes a connection to the local interconnect 140 to connect the local interconnect 140 through the V0 layer to M1.

A back end of the line (BEOL) layer 164, which can include metal structures and dielectric layers to complete a top region and provide electrical access to the devices formed. The BEOL layer 164 includes additional metal layers and vias that can be employed to connect to components and/or route wires from front end of the line (FEOL) structures in any other wiring configuration. A carrier wafer 166 can be bonded to the BEOL layer 164. The carrier wafer 166 provides support and transportability to the wafer 100 for further processing which can include flipping the wafer 100 and removing portions of a bottom side of the semiconductor device under fabrication.

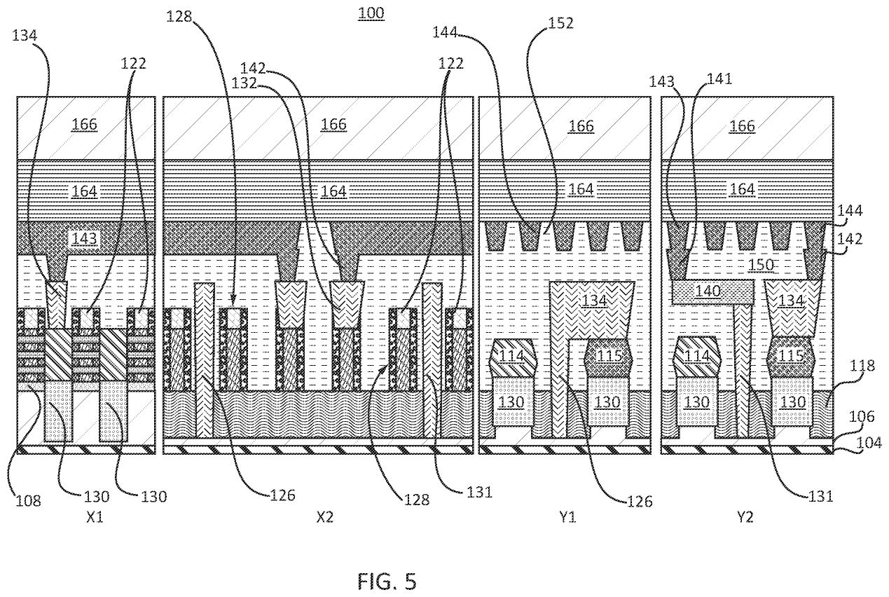

Referring to FIG. 5, to continue processing, the wafer 100 can be flipped to process features on the bottom or backside of the semiconductor device under fabrication. However, for clarity and consistency, the semiconductor device under fabrication will be shown in the FIGS. in a same orientation as previously described with continued and consistent reference to bottom/top. The substrate portion 102 is removed from the backside of the device. The substrate portion 102 can be removed by an etch process that stops on the etch stop layer 104. In an alternate embodiment, a cleave process can be employed to propagate a crack to remove the substrate portion 102 at the etch stop layer 104. The etch stop layer 104 is then removed by an etch process. In an alternate embodiment, a chemical mechanical polish (CMP) process can be employed.

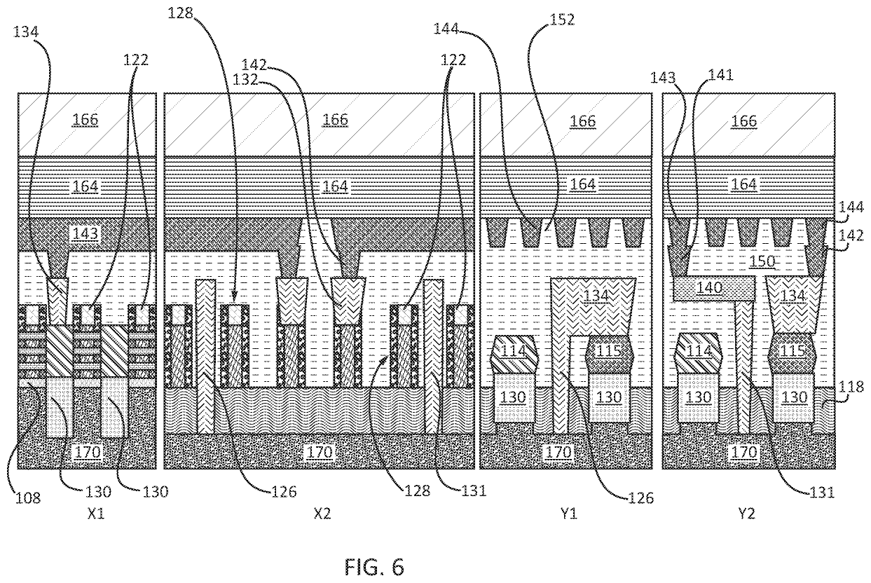

Referring to FIG. 6, with the removal of the etch stop layer 104, the semiconductor portion 106 is exposed. The semiconductor portion 106 is etched back by, e.g., a wet etch process that selectively removes the material of the semiconductor portion 106 relative to the placeholders 130, BDI 108 and shallow trench isolation 118.

A dielectric layer 170 is deposited and fills the recesses left by the removal of the semiconductor portion 106 to contact the placeholders 130. The dielectric layer 170 can then be planarized, e.g., by CMP. The dielectric layer 170 can include the same or different material than dielectric layer 120. The dielectric layer 170 can be deposited or formed by any suitable process. The dielectric layer 170 includes a backside interlevel dielectric layer (BILD).

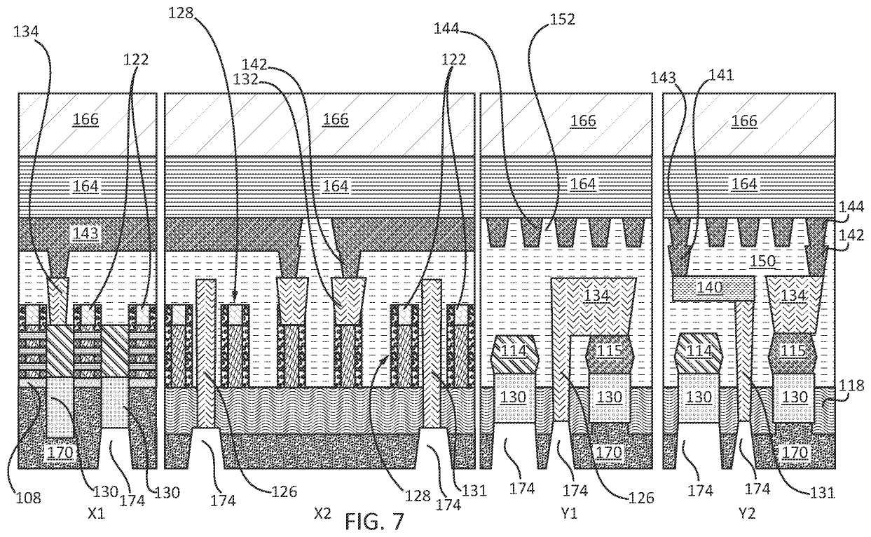

Referring to FIG. 7, backside contact patterning is performed to open up conductive lines through a backside of the semiconductor device under fabrication. A patternable material (not shown) can be deposited or spun onto a surface of the wafer 100 on dielectric layer 170. In one embodiment, the patternable material can include a hard mask or an organic planarization layer (OPL). In some embodiments, an anti-reflective coating (ARC) layer (not shown) may be formed on the patternable material followed by a layer of photoresist formed on the ARC layer. The layer of photoresist can be imaged with an image pattern and developed to form an etch mask. The patternable material can be etched in accordance with the etch mask to form openings 174 at selected locations, e.g., where deep vias 126, 131 and placeholders 130 are to be exposed. The openings 174 can be formed by an anisotropic etch, e.g., a reactive ion etch (RIE) or ion beam etch (IBE), The anisotropic etch, such as a plasma dry etch, is accurately controlled by lithographic processing. The openings 174 that expose the deep vias 126, 131 etch through the dielectric layer 170 as well as a portion of shallow trench isolation 118.

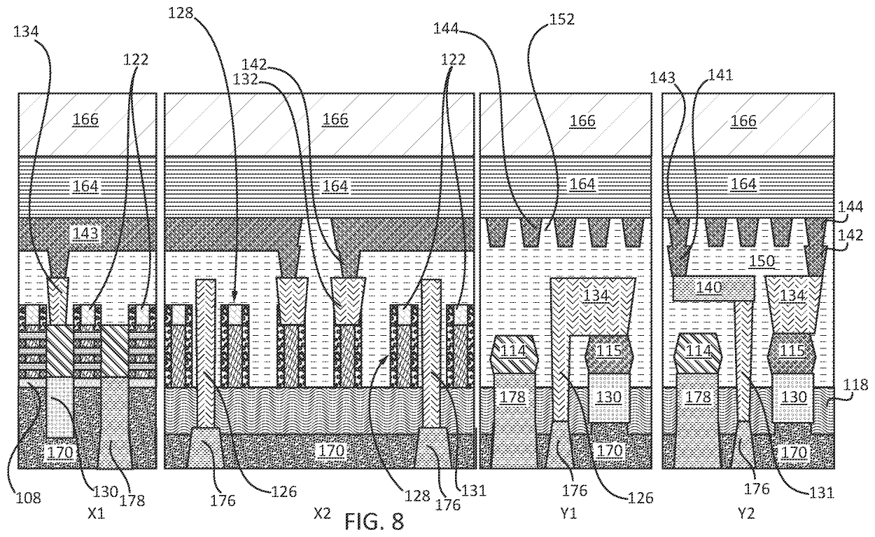

Referring to FIG. 8, an anisotropic etch, e.g., RIE or IBE is performed to remove exposed placeholders 130. A pre-clean of the exposed surfaces of the S/D regions 114, 115 can be performed. In some embodiments, prior to forming backside S/D region contacts 178, a silicide liner, such as Ti, Ni, NiPt can be deposited first, then a diffusion barrier can be formed prior to a conductive fill. The diffusion barrier can include, e.g., TiN, TaN, or similar materials. The diffusion barrier can also be employed with the backside deep via contacts 176.

A conductive fill is performed to fill the openings. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, plasma enhanced CVD (PECVD), atomic layer deposition (ALD) or any other suitable deposition method. The conductive fill can be planarized, e.g., by CMP, to remove access material of the conductive fill to form backside S/D region contacts 178 and backside deep via contacts 176. The contacts 178, 176 from a backside contact layer that includes backside contacts to connect to, e.g., FEOL structures on a backside of the semiconductor device under fabrication.

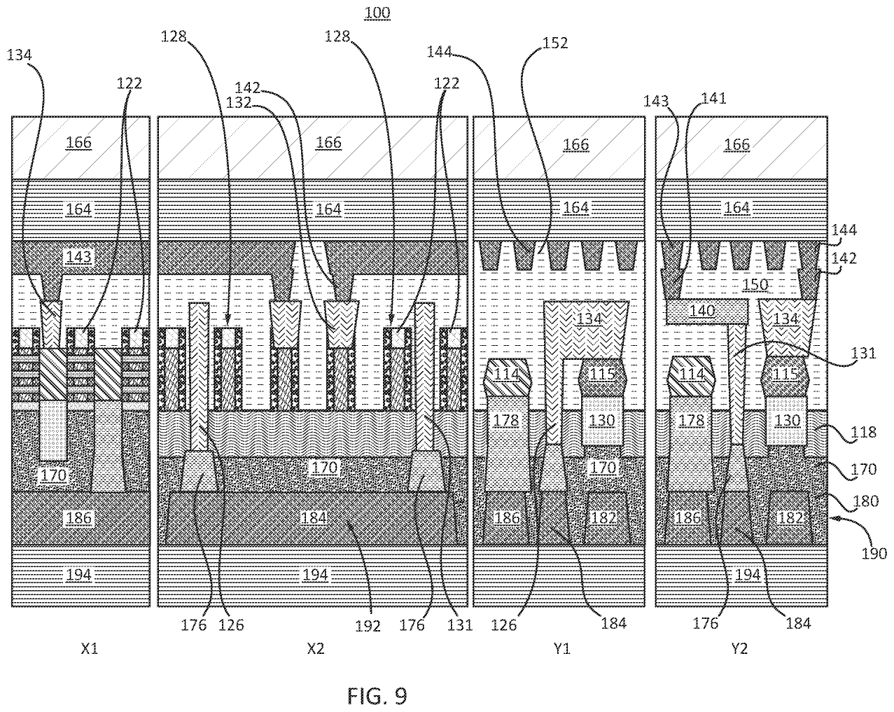

Referring to FIG. 9, processing continues to complete the semiconductor device on wafer 100 with the formation of a backside interconnect layer 190 (e.g., backside M1), which can include metal structures and dielectric layers to complete the bottom side of the device and provide electrical access and power to the devices formed. The backside interconnect layer 190 is formed on the dielectric layer 170, the backside S/D region contacts 178 and backside deep via contacts 176. In an embodiment, the backside interconnect layer 190 can include a plurality of nets. These nets (or circuits) can include positive supply voltage power rails 182 (VDD), negative supply voltage rails 186 (VSS or ground) and signal lines 184. In addition, a backside wire 192 is provided for signal line 184 that can be formed as part of backside interconnect layer 190.

In one embodiment, backside wire 192 connects deep vias 126, 131 and runs transversely to gate structures 128. The backside wire 192 can connect structures from a frontside of the semiconductor device to the backside of the semiconductor device through the active layer level since the deep vias 126, 131 provide a signal path that transverses front end of line (FEOL) structures. The deep via 131 connects to the local interconnect 140 to connect to via 141 and metal line 143 to make connections on a top side of the device. The backside wire 192 can also be employed to make connections to a backside back end of the line (BEOL) layer 194 or to make other connections on the backside or the frontside of the semiconductor device (these can include off-chip connections as well).

The backside wire 192 and the local interconnect 140 can be employed with deep vias 126, 131 in many different and useful configurations. Some of these non-limiting configurations have been illustratively described; however, other configurations and combinations of these configurations are also contemplated. For example, a greater number of deep vias and backside wires can be employed for more complex wire routing between the frontside and backside of the semiconductor device.

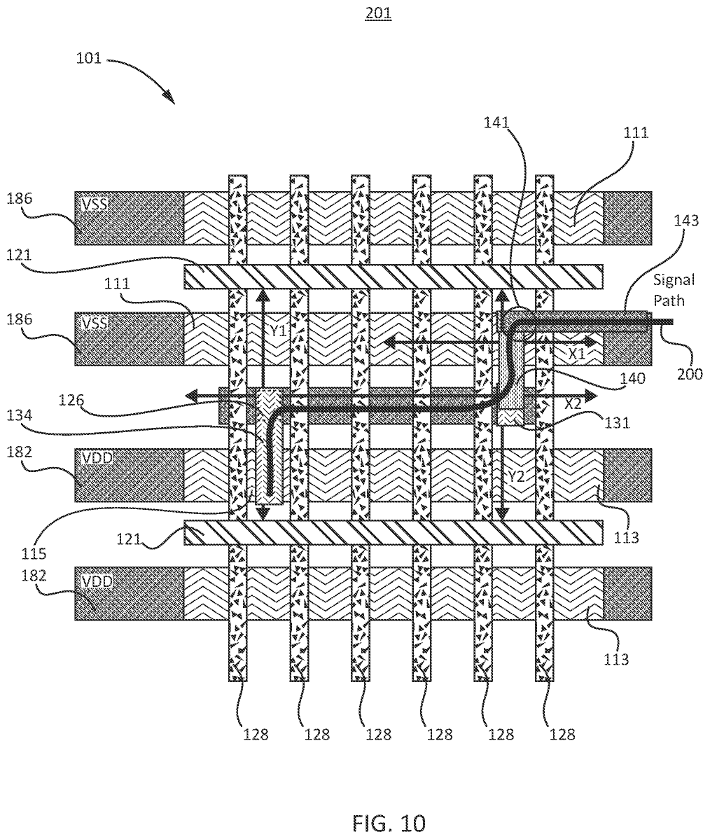

Referring to FIG. 10 with continued reference to FIG. 9, the layout view 101 of a semiconductor device 201 shows a signal path 200 that connects between a frontside and a backside of the semiconductor device 201. BEOL layer 164 connects to metal line 143, via 141, local interconnect 140, deep via 131, contact 176, signal line 184 (backside free wire 192), contact 176, deep via 126, contact 134, S/D region 115. Connections can also be made to BEOL layer 194. It should be understood that other signal paths can by routed in a similar fashion by employing deep vias, local interconnects and backside free wires.

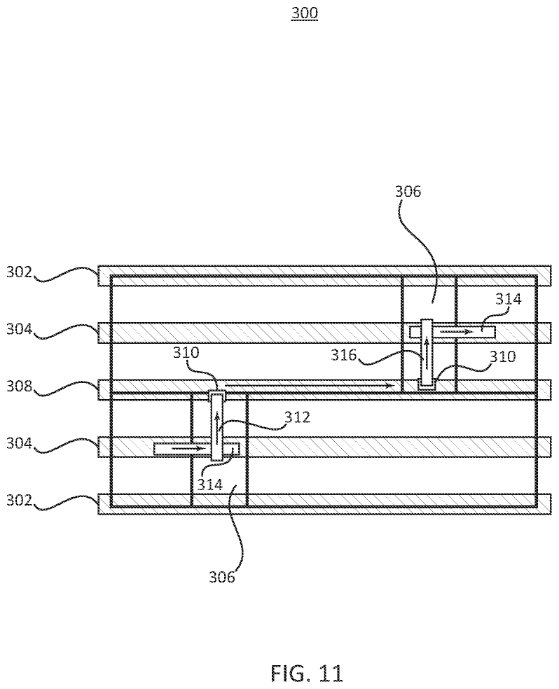

Referring to FIG. 11, backside routing capabilities can be enabled to significantly reduce a number of frontside resources employed for a single net. In a design layout 300, filler cells can exist where circuit components are less dense. Filler cells can be inserted in a layout to fill in gaps in cells after component placement and routing is initially completed. These filler cells provide opportunities to reroute signal or power paths to permit connections with no area penalty.

Layout 300 includes nets 302, 304 and 308. Nets 302 can include VDD. Nets 304 can include VSS and net 308 can include a signal path. Deep vias 310, local interconnects 312, 316, backside wires (net 308), contacts and metal lines 314 can all be employed to provide alternate routing paths. These paths can be centered on or at least partially located in the areas of filler cells 306. In this way, additional wire routing options are provided and with area penalty or with minimal area penalty.

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor- or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
an electrical pathway connecting a frontside of the semiconductor device to a backside of the semiconductor device;
the electrical pathway including:
a backside wire disposed within a backside interconnect layer;
a first deep via connecting to the backside wire, the first deep via extending through a front end of line (FEOL) region; and
a local interconnect that connects to and extends transversely to the first deep via to connect the backside wire to a frontside component.

2. The semiconductor device as recited in claim 1, wherein the local interconnect is disposed within a layer that includes middle of line contacts.

3. The semiconductor device as recited in claim 1, wherein the local interconnect extends over a FEOL structure.

4. The semiconductor device as recited in claim 1, further comprising a second deep via connecting the backside wire to a FEOL structure.

5. The semiconductor device as recited in claim 4, wherein the second deep via is disposed between gate structures of FEOL structures in the FEOL region.

6. The semiconductor device as recited in claim 1, wherein the first deep via is disposed between gate structures of FEOL structures in the FEOL region.

7. The semiconductor device as recited in claim 6, wherein the backside wire is disposed transversely to a longitudinal axis of the gate structures.

8. The semiconductor device as recited in claim 1, wherein the backside wire is disposed between power nets within the backside interconnect layer.

9. The semiconductor device as recited in claim 1, wherein the frontside component includes an M1 metal line.

10. A semiconductor device, comprising:
front end of line (FEOL) structures disposed between a frontside and a backside of the semiconductor device; and
an electrical pathway connecting the frontside to the backside, the electrical pathway including:
a backside wire disposed within a backside interconnect layer;
a first deep via connecting to a first end portion of the backside wire; and
a second deep via connecting to a second end portion the backside wire opposite the first end portion;
wherein the first deep via and the second deep via extend between the FEOL structures to connect the backside wire to the frontside of the semiconductor device.

11. The semiconductor device as recited in claim 10, wherein the first deep via connects to the frontside by a local interconnect that extends transversely to the first deep via.

12. The semiconductor device as recited in claim 11, wherein the local interconnect extends over a source/drain region of one of the FEOL structures.

13. The semiconductor device as recited in claim 10, wherein the first and second deep vias are disposed between gate structures of the FEOL structures.

14. The semiconductor device as recited in claim 13, wherein the backside wire is disposed transversely a longitudinal axis of the gate structures.

15. The semiconductor device as recited in claim 10, wherein the backside wire is disposed between power nets within the backside interconnect layer.

16. The semiconductor device as recited in claim 10, wherein the backside wire connects to an M1 metal line on the frontside.

17. A semiconductor device, comprising:
front end of line (FEOL) structures disposed between a frontside and a backside of the semiconductor device;
a frontside contact layer including frontside contacts to connect to the FEOL structures from the frontside;
a backside contact layer including backside contacts to connect to the FEOL structures from the backside;
a backside wire disposed within a backside interconnect layer;
a first deep via extending through the FEOL structures and connecting to the backside wire using the backside contacts; and
a second deep via extending through the FEOL structures and connecting to the backside wire using the backside contacts;
wherein the first deep via and the second deep via connect the backside wire to the frontside of the semiconductor device using the frontside contacts.

18. The semiconductor device as recited in claim 17, wherein the first deep via connects to the frontside by a local interconnect that extends transversely to the first deep via over a source/drain region of one of the FEOL structures.

19. The semiconductor device as recited in claim 17, wherein the first and second deep vias are disposed between gate structures of the FEOL structures and the backside wire is disposed transverse to the gate structures.

20. The semiconductor device as recited in claim 17, wherein the backside wire is disposed between power nets within the backside interconnect layer.
